(19) United States
(12) Patent Application Publication
(10) Pub. No.: US 2008/0174022 A1
(43) Pub. Date: Jul. 24, 2008

(54) Semiconductor device and fabrication method thereof

(75) Inventors: Hsien-Wei Chen, Tainan (TW); Shin-Puu Jeng, Hsinchu (TW)

Correspondence Address: BIRCH, STEWART, KOLASCH & BIRCH, LLP, P.O. BOX 747, FALLS CHURCH, VA, 22040-0747, US

(73) Assignee: TAIWAN SEMICONDUCTOR MANUFACTURING CO., LTD., Hsin-Chu (TW)

(21) Appl. No.: 11/655,849

(22) Filed: Jan. 22, 2007

(51) Int. Cl. H01L 23/522; H01L 21/768

(52) U.S. Cl. 257/752; 438/645; 257/E23.145; 257/E21.579

(57) ABSTRACT

A semiconductor device. A dielectric layer is disposed on a substrate having a first region and a second region. A first metal layer and a second layer are embedded in the dielectric layer in the first and second regions, respectively, wherein the first and second metal layers are located at the same level and have different thicknesses. A method for fabricating a semiconductor device is also disclosed.

### BACKGROUND OF THE INVENTION

1. Field of the Invention

The invention relates to semiconductor technology and in particular to a semiconductor device with metal layers having different thicknesses and a fabrication method thereof.

2. Description of the Related Art

In the fabrication of the semiconductor devices, size thereof has been continuously reduced to accommodate increased device density. Accordingly, multiple layers may be required to provide a multi-layered interconnect structure. A typical process for forming a multi-layered interconnect structure is a dual damascene process. In the dual damascene process, via openings are first anisotropically etched through an interlayer dielectric (ILD) or intermetal dielectric (IMD) layer by conventional photolithography and etching. A second anisotropically etched opening referred to as a trench opening is then formed overlying one or more of the via openings by a second photolithography and etching. The via openings and the trench opening together make up the dual damascene structure which is subsequently filled with metal followed by a CMP planarization to planarize the wafer process surface and prepare the process surface to form another overlying layer or level in a multi-layered semiconductor device.

However, a scribe line region of the wafer may suffer serious dishing effect during CMP planarization. To solve the problem of CMP topography, the use of dummy metal layers in the scribe line region or in a dummy region of the device region has been developed. The dummy region means a non-used region of the device region or a region of the device region may cause dishing effect during performing CMP. The dummy metal layer can be formed during formation of the multi-layered interconnect structure by a dual damascene process. Unfortunately, other problems are induced by the use of the dummy metal. For example, a parasitic capacitor may be created between the interconnect and the dummy metal, result in increasing of RC (resistance-capacitance) delay and lowering the device performance. Moreover, vibration caused by embedding the dummy metal into the dielectric layer may increase cracking at the boundary of the device region and the scribe line region of the wafer during die sawing process is performed, reducing the device reliability.

Thus, there exists a need for an improved method for fabricating a semiconductor device to reduce cracking while reducing RC delay.

### BRIEF SUMMARY OF INVENTION

A detailed description is given in the following embodiments with reference to the accompanying drawings. A semiconductor device and a method for fabricating the semiconductor device are provided. An embodiment of a semiconductor device comprises a substrate having a first region and a second region. A dielectric layer is disposed on the substrate. A first metal layer and a second layer are embedded in the dielectric layer in the first and second regions, respectively, wherein the first and second metal layers are located at the same level and have different thicknesses.

Another embodiment of a semiconductor device comprises a substrate having a first region and a second region. A dielectric layer is disposed on the substrate. A hard mask layer is disposed on the dielectric layer. A first metal layer and a second metal layer are embedded in the hard mask layer in the first and second regions, respectively. The first and second metal layers are located at the same level and the first metal layer extends into the dielectric layer, such that the first metal layer is thicker than the second metal layer.

An embodiment of a method for fabricating a semiconductor device comprises providing a substrate having a first region and a second region. A dielectric layer is formed on the substrate. The dielectric layer is etched to form a first trench opening in the dielectric layer in the first region. The dielectric layer is etched to form a via opening under the first trench opening and exposing the substrate and simultaneously form a second trench opening in the dielectric layer in the second region, wherein the first and second trench openings have different depths. The first and second trench openings and the via opening are filled with a metal material.

Another embodiment of a method for fabricating a semiconductor device comprises providing a substrate having a first region and a second region. A dielectric layer and a hard mask layer are successively formed on the substrate. A trench pattern is formed in the hard mask layer in the first region to expose the dielectric layer thereunder. A via recess region is formed in the dielectric layer under the trench pattern and a trench recess region is simultaneously formed in the hard layer in the second region. A first trench opening and a via opening are formed in the dielectric layer in the first region by etching the dielectric layer under the trench pattern and a second trench opening is simultaneously formed in the second region by etching the trench recess region and the dielectric layer thereunder, wherein the first and second trench openings have different depths. The hard mask layer is removed. The first and second trench openings and the via opening are filled with a metal material.

Yet another embodiment of a method for fabricating a semiconductor device comprises providing a substrate having a first region and a second region. A dielectric layer, a first hard mask layer and a second hard mask layer are successively formed on the substrate. A trench pattern is formed in the second hard mask layer in the first region to expose the first hard mask layer thereunder. A via pattern is formed in the first hard mask layer under the trench pattern to expose the dielectric layer thereunder and a trench recess region is simultaneously formed in the second hard layer in the second region. A first trench opening and a via opening are formed in the dielectric layer in the first region by etching the first hard mask layer and the dielectric layer under the trench pattern and a second trench opening is simultaneously formed in the second region by etching the trench recess region and the first hard mask layer and the dielectric layer thereunder, wherein the first and second trench openings have different depths. The second and the first hard mask layers are removed. The first and second trench openings and the via opening are filled with a metal material.

### BRIEF DESCRIPTION OF DRAWINGS

The invention can be more fully understood by reading the subsequent detailed description and examples with references made to the accompanying drawings, wherein:

FIGS. 1A to 1E are cross sections of an embodiment of a method for fabricating a semiconductor device;

FIGS. 2A to 2E are cross sections of an embodiment of a method for fabricating a semiconductor device;

FIGS. 3A to 3E are cross sections of an embodiment of a method for fabricating a semiconductor device;

FIGS. 3C-1 to 3E-1 are cross sections of an embodiment of a method for fabricating a semiconductor device after performing the process step shown in FIG. 3B;

FIGS. 3C-2 to 3E-2 are cross sections of an embodiment of a method for fabricating a semiconductor device after performing the process step shown in FIG. 3B; and

FIG. 4 is a cross section of an embodiment of an interconnect structure with a fuse.

### DETAILED DESCRIPTION OF INVENTION

The following description is of the best-contemplated mode of carrying out the invention. This description is provided for the purpose of illustrating the general principles of the invention and should not be taken in a limiting sense. The scope of the invention is best determined by reference to the appended claims. The semiconductor device with metal layers having different thicknesses of this invention will be described below with reference to the accompanying drawings.

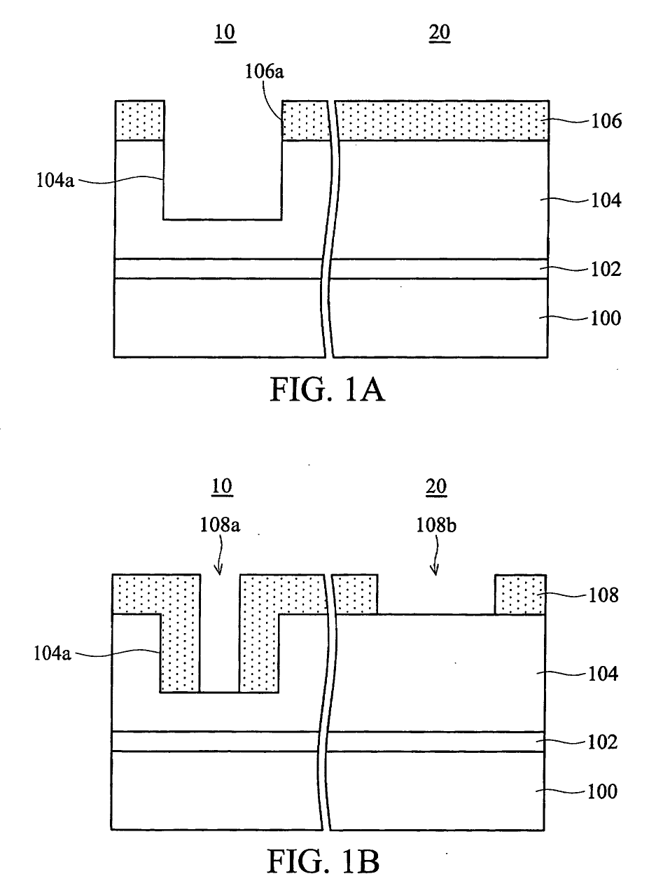

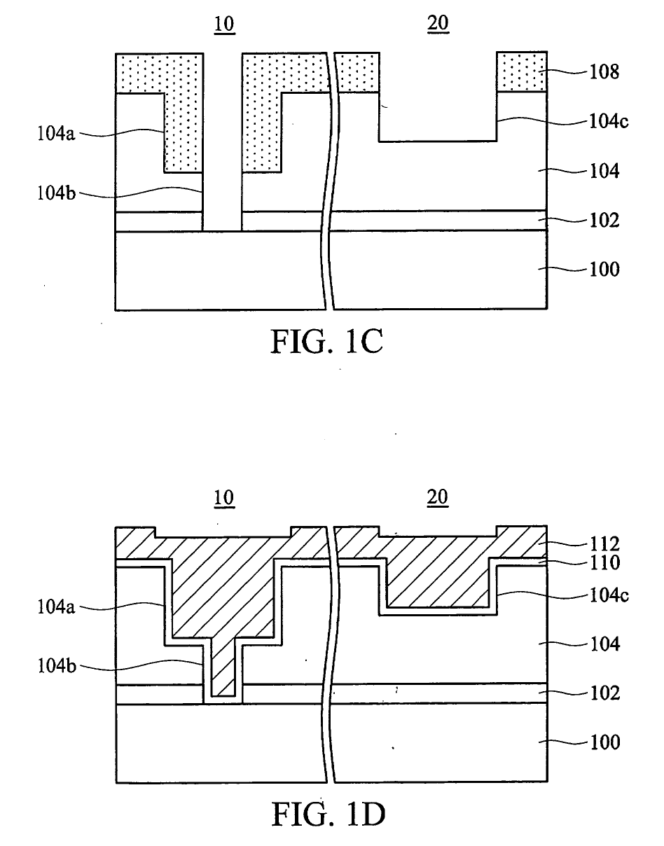

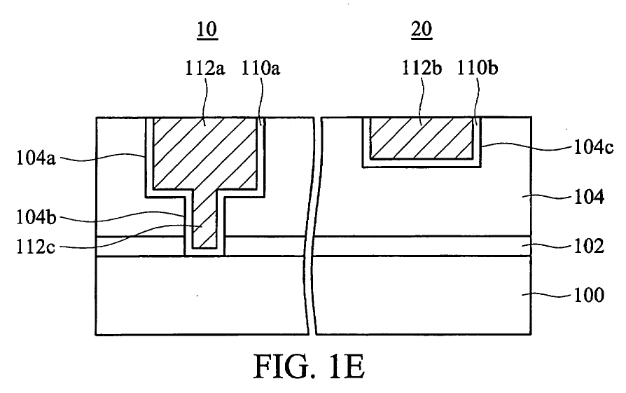

The invention relates to an improved semiconductor device with metal layers having different thicknesses and a method for fabricating the same. FIG. 1E illustrates an embodiment of a semiconductor device with metal layers having different thicknesses. The semiconductor device comprises a substrate 100, such as a semiconductor wafer, having a first region 10 and a second region 20. In this embodiment, the first region 10 of substrate 100 may be a device region and the second region 20 of the substrate 100 may be a scribe line region. In some embodiments, the first and second regions 10 and 20 may be non-dummy and dummy regions of a device region, respectively. A dielectric layer 104 is disposed on the substrate 100. The dielectric layer 104 may serve as an interlayer dielectric (ILD) or intermetal dielectric (IMD) layer. Typically, an etch stop layer 102 is disposed between the dielectric layer 104 and the substrate 100.

The dielectric layer 104 in the device region 10 comprises a dual damascene opening comprising a trench opening 104a and an underlying via/contact opening 104b, such that a first metal layer 112a and an underlying metal plug 112c are embedded in the dielectric layer 104 in the device region 10. Moreover, the dielectric layer 104 in the scribe line region 20 comprises a trench opening 104c, such that a second layer 112b is embedded in the dielectric layer 104 in the scribe line region 20. A barrier line 110a is disposed between the dielectric layer 104 and the first metal layer 112a and another barrier layer 110b is disposed between the dielectric layer 104 and the second metal layer 112b. Here, the first metal layer 112a in the trench opening 104a and the second metal layer 112b in the trench opening 104c are located at the same level and have different thicknesses. For example, the trench opening 104a can have a depth greater than the trench opening 104c, such that the thickness of the first metal layer 112a in the trench opening 104a exceeds that of the second metal layer 112b.

In some embodiments, a hard mask layer 306 may be disposed on the dielectric layer 104. The first metal layer 112a is embedded in the hard mask layer 306 in the device region 10 and extends into the dielectric layer 104. Moreover, the second metal layer 112b is embedded in the hard mask layer 306 in the scribe line region 20, as shown in FIG. 3E-1 or 3E-2. Also, the first and second metal layers 112a and 112b are located at the same level. Since the first metal layer 112a extends into the dielectric layer 104, the first metal layer 112a is thicker than the second metal layer 112b.

FIGS. 1A to 1E are cross sections of an embodiment of a method for fabricating a semiconductor device. In FIG. 1, a substrate 100, such a semiconductor wafer is provided. The substrate 100 comprises a first region 10 and a second region 20. In this embodiment, the first region 10 of substrate 100 may be a device region and the second region 20 of the substrate 100 may be a scribe line region. The substrate 100 in the device region 10 may contain a variety of elements, including, for example, transistors, resistors, and other semiconductor elements as are well known in the art. To simplify the diagram, a flat substrate is depicted.

A dielectric layer 104, serving as an interlayer dielectric (ILD) or intermetal dielectric (IMD) layer overlies the substrate 100. For example, the dielectric layer 104 may be silicon dioxide, phosphosilicate glass (PSG), borophosphosilicate glass (BPSG). Preferably, the dielectric layer 106 comprises a low dielectric constant (k) material to achieve low RC time constant (resistance-capacitance), such as fluorosilicate glass (FSG). The dielectric layer 104 can be formed by conventional deposition, such as plasma enhanced chemical vapor deposition (PECVD), low pressure CVD (LPCVD), atmospheric pressure CVD (APCVD), high-density plasma CVD (HDPCVD) or other suitable CVD. Typically, an etch stop or diffusion barrier layer 102, such as silicon nitride (SiN or Si₃N₄), silicon oxynitride (SiON), silicon carbide (SiC), silicon oxycarbide (SiOC), or combinations thereof, is formed on the substrate 100 by conventional deposition prior to formation of the dielectric layer 104.

A photoresist layer 106 with at least one trench pattern 106a is formed on the dielectric layer 104 in the device region 10 by photolithography. A conventional etching process, such as a reactive ion etching (RIE), is then carried out to form a trench opening 104a in the dielectric layer 104 in the device region 10.

In FIG. 1B, after removal of the photoresist layer 106 shown in FIG. 1A, a photoresist layer 108 is formed on the dielectric layer 104 by photolithography, comprising at least one via pattern 108a above the trench opening 104a and comprising at least one trench pattern 108b in the scribe line region 20. The dielectric layer 104 is etched using the photoresist layer 108 as an etch mask, to form a via opening 104b under the trench opening 104a through the dielectric layer 104 and the etch stop layer 102 to expose the substrate 100, as shown in FIG. 1C. At the same time, another trench opening 104c is formed in the dielectric layer 104 in the scribe line region 20. Since the trench opening 104c is simultaneously formed with the via opening 104b, rather than simultaneously with the trench opening 104a, the trench openings 104a and 104c have different depths. In this embodiment, the depth of the trench opening 104a exceeds that of the trench opening 104c.

In FIG. 1D, after removal of the photoresist layer 108 shown in FIG. 1C, a metal material 112, such as copper, aluminum, or other well known interconnect material, is formed over the dielectric layer 104 and fills the trench and via openings 104a and 104c in the device region 10 and the trench opening 104b in the scribe line region 20. Typically, a conformable barrier layer 110, such as TiN, TaN, or Ti may line the trench and via openings 104a and 104c in the device region 10 and the trench opening 104b in the scribe line region 20 prior to deposition of the metal interconnect material 112.

In FIG. 1E, the excess metal material 112 and barrier layer 110 over the trench and via openings 104a and 104c in the device region 10 and the trench opening 104b in the scribe line region 20 are removed by polishing, such as chemical mechanical polishing (CMP), to form a first metal layer 112a and a metal plug 112c surrounded by a barrier liner 110a in the trench and via openings 104a and 104b in the device region 10, serving as a metal interconnect. At the same time, a second metal layer 112b surrounded by a barrier liner 110b is formed in the trench opening 104c in the scribe line region 20, serving as a dummy metal layer for CMP.

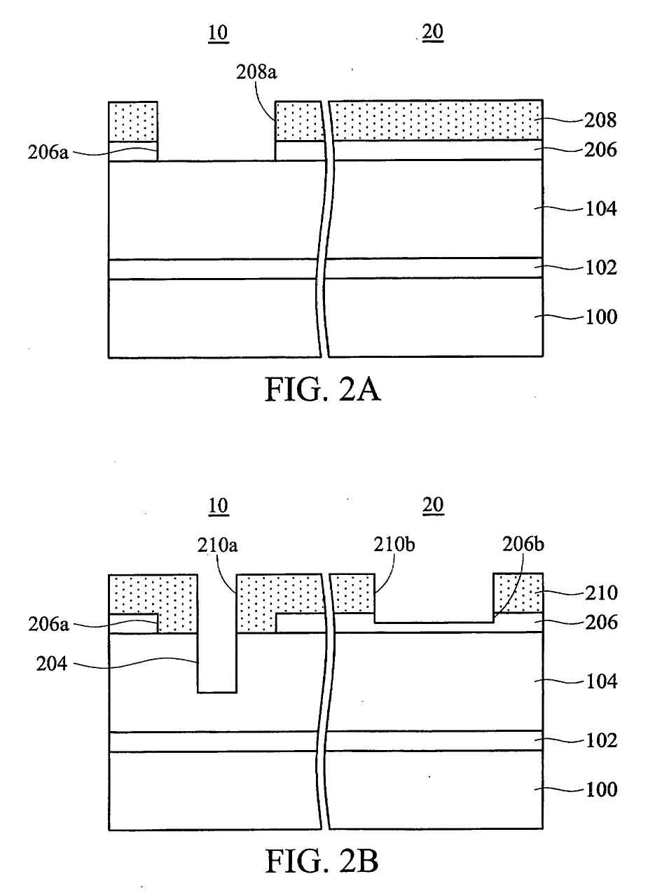

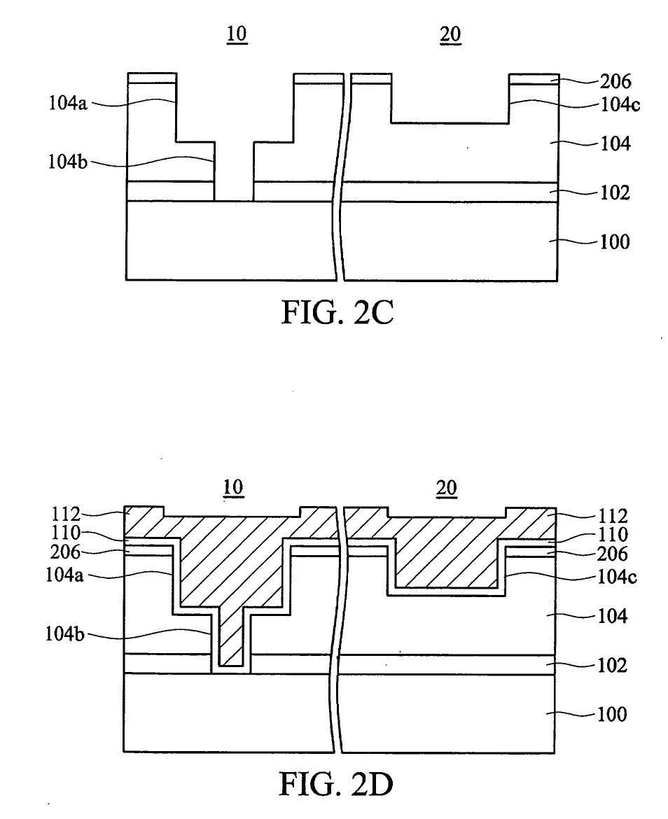

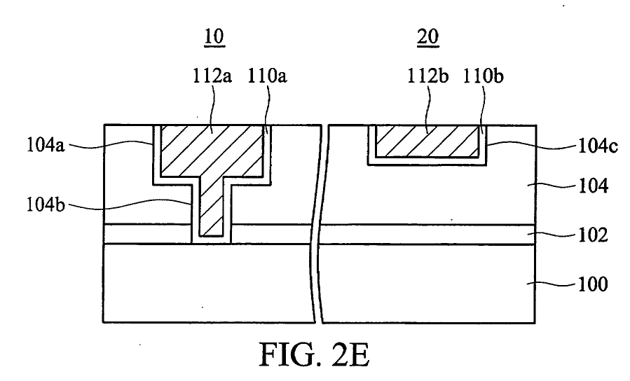

FIGS. 2A to 2E are cross sections of an embodiment of a method for fabricating a semiconductor device. Elements in FIGS. 2A to 2E the same as in FIGS. 1A to 1E are labeled the same and not described again. In FIG. 2A, a hard mask layer 206, such as silicon nitride (SiN or Si₃N₄), silicon oxynitride (SiON), or silicon carbide (SiC), is formed on a substrate 100 having an etch stop layer 102 and a dielectric layer 104 thereon. In this embodiment, the substrate 100 may also comprise a device region 10 and a scribe line region 20. A photoresist layer 208 with at least one trench pattern 208a is formed on the hard mask layer 206 in the device region 10 by photolithography. A conventional etching process, such as RIE, is then carried out to form a trench pattern 206a in the hard mask layer 206 in the device region 10 to expose the dielectric layer 104 thereunder.

In FIG. 2B, after removal of the photoresist layer 208 shown in FIG. 2A, a photoresist layer 210 is formed on the hard mask layer 206 and the dielectric layer 104 by photolithography, comprising at least one via pattern 210a above the trench pattern 206a and comprising at least one trench pattern 210b in the scribe line region 20. The hard mask layer 206 under the trench pattern 210b and the dielectric layer 104 under the via pattern 210a are etched to form a trench recess region 206b in the hard layer 206 in the scribe line region 20 and simultaneously form a via recess region 204 under the trench pattern 206a in the device region 10.

In FIG. 2C, after removal of the photoresist layer 210 shown in FIG. 2B, a trench opening 104a and a via opening 104b are formed in the dielectric layer 104 and through the etch stop layer 102 in the device region 10 by etching the dielectric layer 104 under the trench pattern 206a. At the same time, another trench opening 104c is formed in the dielectric layer 104 in the scribe line region 20 by etching the trench recess region 206b shown in FIG. 2B and the dielectric layer 104 thereunder. Since the trench opening 104c is formed by etching the hard mask layer 206 and the underlying dielectric layer 104 and the trench opening 104a is formed by etching the dielectric layer 104 only, the trench openings 104a and 104c have different depths. For example, the depth of the trench opening 104a also exceeds that of the trench opening 104c.

Thereafter, similar process steps as shown in FIGS. 1D to 1E are successively performed to form a first metal layer 112a and a metal plug 112c surrounded by a barrier liner 110a in the trench and via openings 104a and 104b in the device region 10 and simultaneously form a second metal layer 112b surrounded by a barrier liner 110b in the trench opening 104c in the dielectric layer 104 in the scribe line region 20, as shown in FIGS. 2D to 2E. Note that the hard mask layer 206 is typically removed during performing CMP.

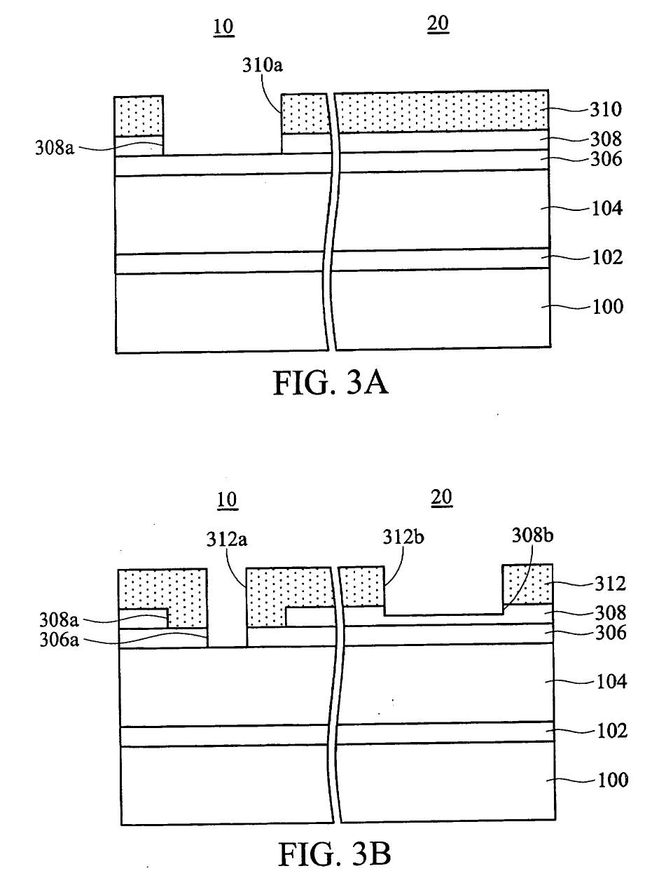

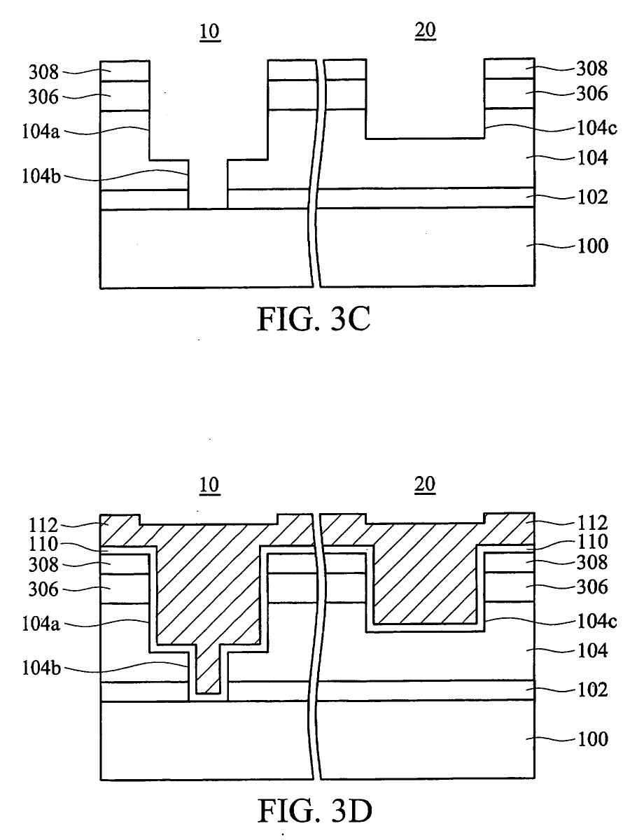

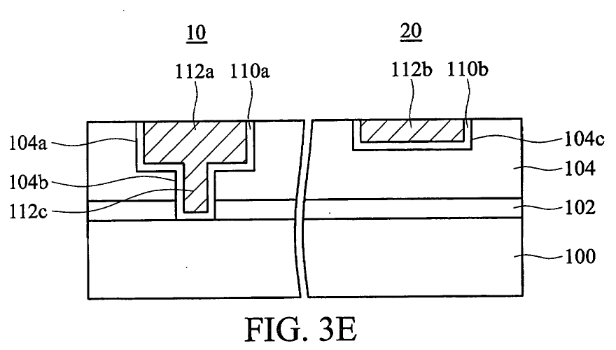

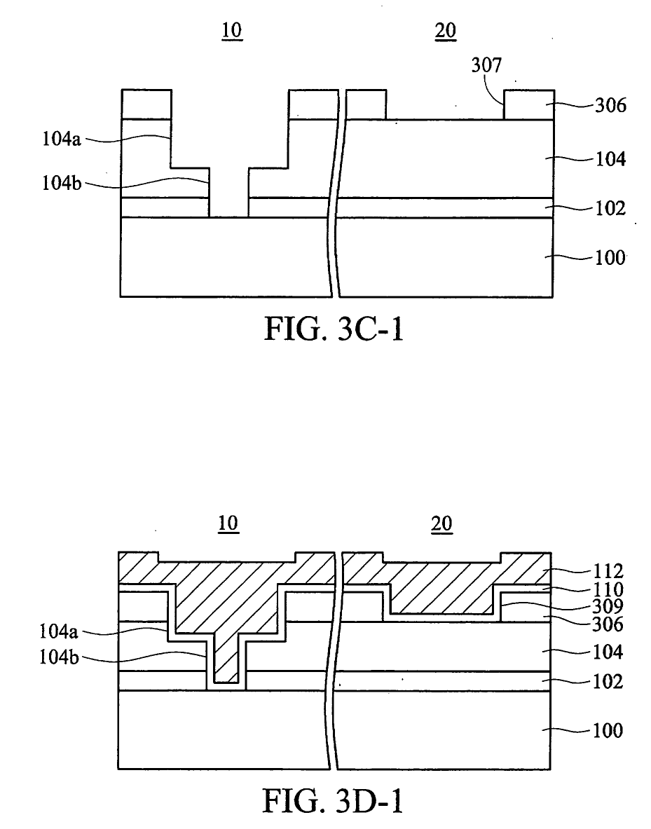

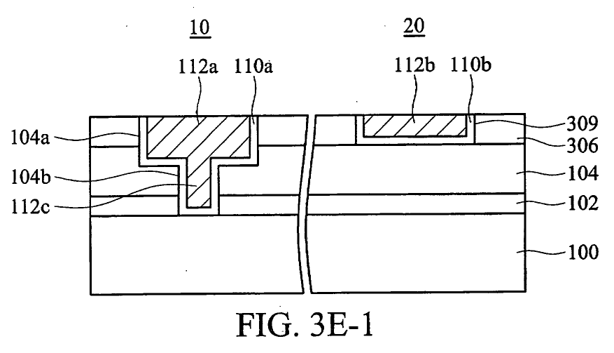

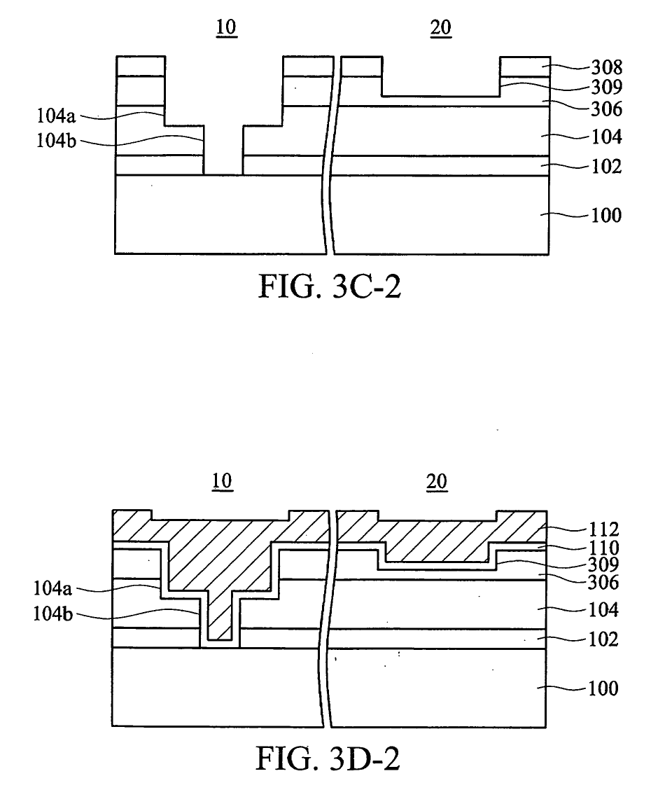

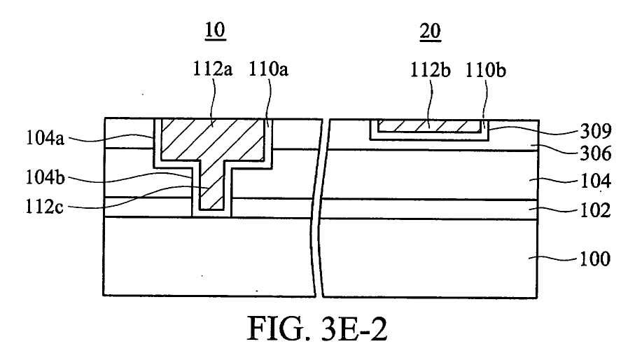

FIGS. 3A to 3E are cross sections of an embodiment of a method for fabricating a semiconductor device. Elements in FIGS. 3A to 3E the same as in FIGS. 1A to 1E are labeled the same and not described again. In FIG. 3A, a first hard mask layer 306 and a second hard mask layer 308 are successively formed on a substrate 100 having an etch stop layer 102 and a dielectric layer 104 thereon. In this embodiment, the etching rate of the first hard mask layer 306 exceeds that of the second hard mask layer 308. For example, the first hard mask layer 306 may be composed by SiOC, SiON and the second hard mask layer 308 may be composed by TiN, SiN, Si3N4, SiC. However, the etch selectivity rate is dependent on the plasma gas and dielectric material. Moreover, the substrate 100 may also comprise a device region 10 and a scribe line region 20. A photoresist layer 310 with at least one trench pattern 310a is formed on the second hard mask layer 308 in the device region 10 by photolithography. A conventional etching process, such as RIE, is then carried out to form a trench pattern 308a in the second hard mask layer 308 in the device region 10 to expose the first hard mask layer 306 thereunder.

In FIG. 3B, after removal of the photoresist layer 310 shown in FIG. 2A 3A, a photoresist layer 312 is formed on the second and first hard mask layers 308 and 306 by photolithography, comprising at least one via pattern 312a above the trench pattern 308a and comprising at least one trench pattern 312b in the scribe line region 20. The first hard mask layer 306 under the via pattern 312a is etched to form a via pattern 306a therein and under the trench pattern 308a to expose the dielectric layer 104. At the same time, a trench recess region 308b is formed after etching the second hard mask layer 308 under the trench pattern 312b due to a relatively lower etching rate with respect to that of the first hard mask layer 306.

In FIG. 3C, after removal of the photoresist layer 312 shown in FIG. 3B, a trench opening 104a and a via opening 104b are formed in the dielectric layer 104 in the device region 10 by etching the first hard mask layer 306 and the dielectric layer 104 under the trench pattern 308a shown in FIG. 3B. At the same time, another trench opening 104c is formed in the dielectric layer 104 in the scribe line region 20 by etching the trench recess region 308b and the first hard mask layer 306 and the dielectric layer 104 thereunder. As a result, the trench openings 104a and 104c have different depths. For example, the depth of the trench opening 104a exceeds that of the trench opening 104c, as shown in FIG. 3C.

Thereafter, similar process steps as shown in FIGS. 1D to 1E are successively performed to form a first metal layer 112a and a metal plug 112c surrounded by a barrier liner 110a in the trench and via openings 104a and 104b in the device region 10 and simultaneously form a second metal layer 112b surrounded by a barrier liner 110b in the trench opening 104c in the dielectric layer 104 in the scribe line region 20, as shown in FIGS. 3D to 3E. Note that the second and first hard mask layers 308 and 306 are removed during performing CMP. In some embodiments, the second hard mask layer 308 is removed during etching to form the trench openings 104a and 104c and the via opening 104b.

FIGS. 3C-1 to 3E-1 are cross sections of an embodiment of a method for fabricating a semiconductor device after the process step shown in FIG. 3B. Unlike the embodiment mentioned in FIGS. 3A to 3E, the thickness of the first hard mask layer 306 may be increased, such that a trench opening 307 is only formed in the first hard mask layer 306 in the scribe line region 20 during formation of the trench and via openings 104a and 104b in the device region 10, as shown in FIG. 3C-1. That is, the trench opening 307 exposes the dielectric layer 104 without extending into the dielectric layer 104. Thereafter, similar process steps as shown in FIGS. 1D to 1E are successively performed to form a first metal layer 112a and a metal plug 112c surrounded by a barrier liner 110a in the trench and via openings 104a and 104b in the device region 10 and simultaneously form a second metal layer 112b surrounded by a barrier liner 110b in the trench opening 307 in the first mask hard layer 306 in the scribe line region 20, as shown in FIGS. 3D-1 to 3E-1.

FIGS. 3C-2 to 3E-2 are cross sections of an embodiment of a method for fabricating a semiconductor device after performing the process step shown in FIG. 3B. Unlike the embodiment mentioned in FIGS. 3C-1 to 3E-1, the thickness of the first hard mask layer 306 may be further increased, such that a trench recess region 309 is formed in the first hard mask layer 306 in the scribe line region 20 during formation of the trench and via openings 104a and 104b in the device region 10, as shown in FIG. 3C-2. That is, the trench recess region 309 does not penetrate the first hard mask layer 306. Thereafter, similar process steps as shown in FIGS. 1D to 1E are successively performed to form a first metal layer 112a and a metal plug 112c surrounded by a barrier liner 110a in the trench and via openings 104a and 104b in the device region 10 and simultaneously form a second metal layer 112b surrounded by a barrier liner 110b in the trench recess region 309 in the first mask hard layer 306 in the scribe line region 20, as shown in FIGS. 3D-2 to 3E-2.

According to the invention, the dummy metal layer disposed in the scribe line region can be thinner than that of the metal layer disposed in the device region, such that vibration during die sawing is avoided, thereby reducing cracking at the boundary between the device region and the scribe line region. Accordingly, device reliability is increased. Moreover, the parasitic capacitance between the metal layer in the device region and that in the scribe line region is reduced due to a thinner dummy metal layer, thereby reducing RC delay. Moreover, as mentioned, as the dummy metal layer (i.e. the second metal layer 112b) is formed in the dummy region of the device region, the parasitic capacitance between the first and second metal layers 112a and 112b is also reduced, thereby reducing RC delay. Accordingly, the device performance is increased. Additionally, since the dummy metal layer disposed in the scribe line region (or in the dummy region of the device region) and the metal layer disposed in the non-dummy region of the device region are formed at the same time, no additional mask for lithography is needed.

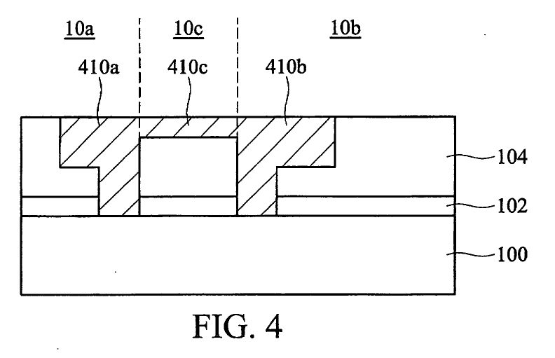

Additionally, while, in the embodiments disclosed, the second metal layer serves as a dummy metal layer in the scribe line region or in the dummy region of the device region, the invention is not limited thereto and can further be utilized in a fuse fabrication. FIG. 4 is a cross section of an embodiment of an interconnect structure with a fuse, in which the same reference numbers as FIG. 1E are used. The interconnect structure comprises a substrate 100 having interconnect regions 10a and 10b and a fuse region 10c. An etch stop layer 102 and a dielectric layer 104 are successively disposed on the substrate. The dielectric layer 104 comprises at least one pair of dual damascene openings (comprising a trench opening and an underlying via opening) in the interconnect region 10a and 10b, respectively, and at least one opening in the fuse region 10c. The opening in the fuse region 110c laterally extends to the trench openings in the interconnect regions 10a and 10b and is shallower than that of the trench openings. The openings with different depths can be accomplished by methods shown in the disclosed embodiments. After metallization, interconnects 410a and 410b are formed in the interconnect regions 10a and 10b, respectively, and a fuse 410c is simultaneously formed in the fuse region 10c to electrically connect interconnects 410a and 410b. Since the fuse 410c is thinner than the trench portions of interconnects 410a and 410b, lower current flux is required to blow the fuse 410c or blowing time for the fuse 410c is reduced.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate having a first region and a second region;
a dielectric layer disposed on the substrate; and
a first metal layer and a second layer embedded in the dielectric layer in the first and second regions, respectively, wherein the first and second metal layers are located at the same level and have different thicknesses.

2. The semiconductor device as claimed in claim 1, wherein the first region is a device region and the second region is a scribe line region.

3. The semiconductor device as claimed in claim 2, wherein the thickness of the first metal layer exceeds that of the second metal layer.

4. The semiconductor device as claimed in claim 1, wherein the first and second regions are a non-dummy region and a dummy region of a device region, respectively.

5. The semiconductor device as claimed in claim 4, wherein the thickness of the first metal layer exceeds that of the second metal layer.

6. The semiconductor device as claimed in claim 1, further comprising a metal plug disposed in the dielectric layer under the first metal layer.

7. The semiconductor device as claimed in claim 1, wherein the first region is an interconnect region and the second region is a fuse region.

8. The semiconductor device as claimed in claim 7, wherein the second metal layer extends to and is thinner than the first metal layer.

9. A semiconductor device, comprising:
a substrate having a first region and a second region;
a dielectric layer disposed on the substrate;
a hard mask layer disposed on the dielectric layer; and
a first metal layer and a second metal layer embedded in the hard mask layer in the first and second regions, respectively;
wherein the first and second metal layers are located at the same level and the first metal layer extends into the dielectric layer, such that the first metal layer is thicker than the second metal layer.

10. The semiconductor device as claimed in claim 9, wherein the first region is a device region and the second region is a scribe line region.

11. The semiconductor device as claimed in claim 9, wherein the second metal layer is surrounded by the hard mask layer except the top surface of the second metal layer.

12. The semiconductor device as claimed in claim 9, further comprising a metal plug disposed in the dielectric layer under the first metal layer.

13. The semiconductor device as claimed in claim 9, wherein the first and second regions are a non-dummy region and a dummy region of a device region, respectively.

14. The semiconductor device as claimed in claim 9, wherein the first region is an interconnect region and the second region is a fuse region.

15. The semiconductor device as claimed in claim 14, wherein the second metal layer extends to the first metal layer.

16. A method for fabricating a semiconductor device, comprising:
providing a substrate having a first region and a second region;
forming a dielectric layer on the substrate;
etching the dielectric layer to form a first trench opening in the dielectric layer in the first region;
etching the dielectric layer to form a via opening under the first trench opening and exposing the substrate and simultaneously form a second trench opening in the dielectric layer in the second region, wherein the first and second trench openings have different depths; and
filling the first and second trench openings and the via opening with a metal material.

17. The method as claimed in claim 16, wherein the first region is a device region and the second region is a scribe line region.

18. The method as claimed in claim 17, wherein the depth of the first trench opening exceeds that of the second trench opening.

19. The method as claimed in claim 16, wherein the first and second regions are a non-dummy region and a dummy region of a device region, respectively.

20. The method as claimed in claim 19, wherein the depth of the first trench opening exceeds that of the second trench opening.

21. The method as claimed in claim 16, wherein the first region is an interconnect region and the second region is a fuse region.

22. The method as claimed in claim 21, wherein the second trench opening extends to and shallower than the first trench opening.

23. A method for fabricating a semiconductor device, comprising:
providing a substrate having a first region and a second region;
successively forming a dielectric layer and a hard mask layer on the substrate;
forming a trench pattern in the hard mask layer in the first region to expose the dielectric layer thereunder;
forming a via recess region in the dielectric layer under the trench pattern and simultaneously forming a trench recess region in the hard layer in the second region;
forming a first trench opening and a via opening in the dielectric layer in the first region by etching the dielectric layer under the trench pattern and simultaneously forming a second trench opening in the second region by etching the trench recess region and the dielectric layer thereunder, wherein the first and second trench openings have different depths;
removing the hard mask layer; and
filling the first and second trench openings and the via opening with a metal material.

24. The method as claimed in claim 23, wherein the first region is a device region and the second region is a scribe line region.

25. The method as claimed in claim 24, wherein the depth of the first trench opening exceeds that of the second trench opening.

26. The method as claimed in claim 23, wherein the first and second regions are a non-dummy region and a dummy region of a device region, respectively.

27. The method as claimed in claim 26, wherein the depth of the first trench opening exceeds that of the second trench opening.

28. The method as claimed in claim 23, wherein the first region is an interconnect region and the second region is a fuse region.

29. The method as claimed in claim 23, wherein the second trench opening extends to and shallower than the first trench opening.

30. A method for fabricating a semiconductor device, comprising:
providing a substrate having a first region and a second region;
successively forming a dielectric layer, a first hard mask layer, and a second hard mask layer on the substrate;
forming a trench pattern in the second hard mask layer in the first region to expose the first hard mask layer thereunder;
forming a via pattern in the first hard mask layer under the trench pattern to expose the dielectric layer thereunder and simultaneously forming a trench recess region in the second hard layer in the second region;
forming a first trench opening and a via opening in the dielectric layer in the first region by etching the first hard mask layer and the dielectric layer under the trench pattern and simultaneously forming a second trench opening in the second region by etching the trench recess region and the first hard mask layer and the dielectric layer thereunder, wherein the first and second trench openings have different depths;
removing the second and the first hard mask layers; and
filling the first and second trench openings and the via opening with a metal material.

31. The method as claimed in claim 30, wherein the first region is a device region and the second region is a scribe line region.

32. The method as claimed in claim 31, wherein the depth of the first trench opening exceeds that of the second trench opening.

33. The method as claimed in claim 30, wherein the first and second regions are a non-dummy region and a dummy region of a device region, respectively.

34. The method as claimed in claim 33, wherein the depth of the first trench opening exceeds that of the second trench opening.

35. The method as claimed in claim 30, wherein the first region is an interconnect region and the second region is a fuse region.

36. The method as claimed in claim 35, wherein the second trench opening extends to and shallower than the first trench opening.
